(19) United States
(12) Patent Application Publication
(10) Pub. No.: US 2024/0007055 A1
(43) Pub. Date: Jan. 4, 2024

(54) Loudspeaker Power Amplifier and Loudspeaker

(71) Applicant: Sennheiser electronic GmbH & Co. KG, Wedemark (DE)

(72) Inventors: Johannes Storch, Wedemark (DE); Stephan Leschka, Potsdam (DE)

(73) Assignee: Sennheiser electronic GmbH & Co. KG, Wedemark (DE)

(21) Appl. No.: 18/216,174

(22) Filed: Jun. 29, 2023

(30) Foreign Application Priority Data
Jul. 1, 2022 (DE) 102022116446.2

(51) Int. Cl. H03F 1/26; H03F 3/21; H03F 1/32; H04R 3/04

(52) U.S. Cl. CPC H03F 1/26; H03F 3/211; H03F 2200/03; H04R 3/04; H03F 1/32

(57) ABSTRACT

A loudspeaker power amplifier comprising a digital amplifier is provided. The amplifier has a negative input and a positive input as well as a negative output and a positive output. The power amplifier further comprises a first feedback circuit from the positive output to the negative input, and a second feedback circuit from the negative output to the positive input. The first and the second feedback circuit each have a first and a second amplification circuit.

### CROSS-REFERENCE TO RELATED APPLICATIONS

This application claims priority to German Patent Application No. 102022116446.2, filed Jul. 1, 2022, the entirety of which is herein incorporated by reference.

### FIELD OF DISCLOSURE The present invention relates to a loudspeaker power amplifier and a loudspeaker.

### BACKGROUND

An input signal of a loudspeaker is typically amplified by means of a power amplifier and then converted into audio signals by means of the electroacoustic response transducer of the loudspeaker.

### SUMMARY OF THE INVENTION

It is the object of the present invention to provide a digital loudspeaker power amplifier and a loudspeaker with reduced inherent noise and improved linearity.

This object is achieved by a loudspeaker power amplifier according to claim 1 and by a loudspeaker according to claim 5.

Thus, a loudspeaker power amplifier comprising a digital amplifier is provided which has a negative input, a positive input, a negative output and a positive output. The amplifier has a first feedback circuit from the positive input to the negative input and a second feedback circuit from the negative output to the positive input. The first and second feedback circuit each have a first and a second active amplification circuit.

According to one aspect, a first smoothing circuit is provided at the positive output for smoothing the output signals of the positive output and a second smoothing circuit is provided at the negative output for smoothing the output signals of the negative output.

According to one aspect the first and second active amplifier circuit each have a frequency response with an amplification H and a phase P. The amplification H at a frequency of 1 kHz is greater than 6 dB and the amplification H at frequencies above 70 kHz is less than 1 dB. The phase P in the frequency range of 70 kHz to 500 kHz is above −15°.

A loudspeaker power amplifier with a digital amplifier is provided which has two inputs and two outputs and a first and a second feedback circuit. The first feedback circuit extends from the second output to the first output of the amplifier. The second feedback circuit extends from the first output to the second input of the digital amplifier. The first and second feedback circuit each have a first and second active amplification circuit.

Thus, through a combination of active and passive negative feedback, both the properties of the power amplifier (Class D amplifier) and also the effects of an output low-pass filter on the output signal can be improved. Furthermore, a constant amplification for amplifiers can be optimally adjusted.

As a result of the active amplification in the feedback of the digital amplifier, the inherent noise of the digital amplifier can be reduced.

According to one aspect of the present invention, the power amplifier has a smoothing circuit in the form of an output low-pass filter at the second output for smoothing the output signals of the second output and a second smoothing circuit at the first output for smoothing the output signals of the first output.

According to a further aspect of the present invention, the first and second active amplifier circuit brings about an amplification in the audio frequency range and can have an amplification of 1 for frequencies above the audio frequency range. The first and second active amplification in the feedback loop is therefore only effective for frequencies in the audio range. For frequencies above the audio range no amplification is accomplished. This is advantageous because the stability of the complete circuit is thus increased.

According to a further aspect of the present invention, the first and second feedback circuit is configured to feed back an alternating voltage in each case.

The invention also relates to a loudspeaker with a loudspeaker power amplifier described above.

Thus, a loudspeaker having an input connection, a power amplifier and two feedback loops for the power amplifier is provided. The two feedback loops each have an active amplifier.

The power amplifier is configured as a digital amplifier and delivers a pulse-width modulated signal at its output. The power amplifier can have a positive input and a negative input. A smoothing of the output signals by means of a smoothing unit takes place at the output puts (+output; −output). The smoothed output signals are then guided by means of a feedback loop to the inputs (+input; −input) of two amplifiers. One amplifier is assigned to the negative connection and another amplifier is assigned to the positive connection. An active return of the output signals of the power amplifier is thus made possible. By providing the active amplification in the return loop of the digital amplifier, this results in an amplification in this return loop. This amplification is optionally provided in the audio frequency range and can reduce any distortion produced. At higher frequencies the amplifier can have an amplification of 1.

The amplification H of the first and second active amplifier circuit 150, 160 can be high up to 1 kHz, for example, e.g. greater than 6 dB and can then decrease until it is less than 1 dB from 70 kHz. The phase P decreases slowly between 100 Hz and 1 kHz. A continuous decrease takes place between 1 kHz and about 10 kHz. The phase then increases again at higher frequencies and approaches 0°. In a range from 70 kHz to at least 500 kHz the phase remains above −15°.

The feedback circuits are each guided from the negative output to the positive input or from the positive output to the negative input of the power amplifier U14 in order to achieve a negative feedback.

Further embodiments of the invention are the subject matter of the dependent claims.

### BRIEF DESCRIPTION OF THE DRAWINGS

Advantages and exemplary embodiments of the invention are explained in detail hereinafter with reference to the drawings.

FIG. 1 shows a circuit diagram of a loudspeaker amplifier,

FIG. 2 shows a circuit diagram of an alternative loudspeaker amplifier,

FIG. 3 shows a circuit diagram of another loudspeaker amplifier,

FIG. 4 shows a circuit diagram of another loudspeaker amplifier.

FIG. 5 shows a diagram of a frequency response of an active amplifier circuit.

### DETAILED DESCRIPTION

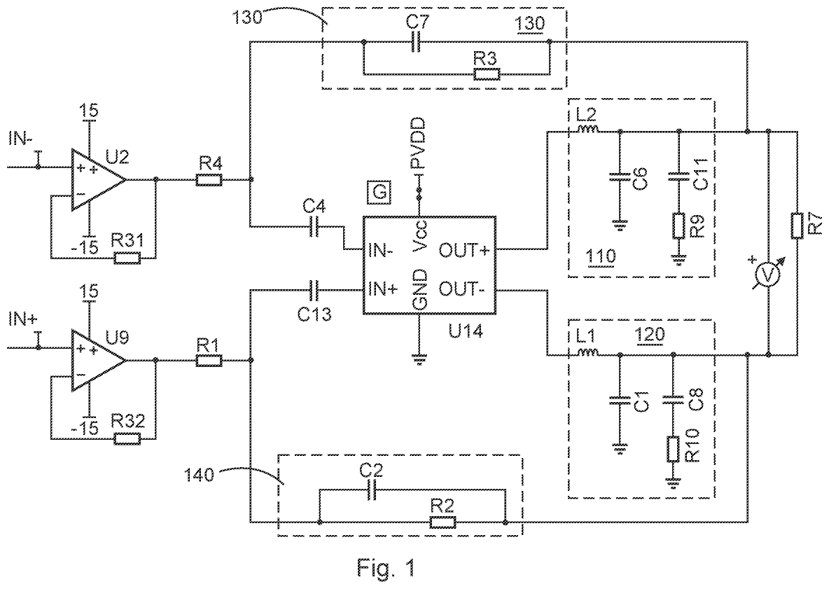

FIG. 1 shows a circuit diagram of a loudspeaker amplifier. Via the inputs in−, in+ audio input signals (+; −signals) can be input into the circuit. A pre-amplifier U2 with a feedback loop having a resistance R31 is provided at the negative input in−. A resistance R4 is provided at the output of the amplifier U2. A pre-amplifier U9 having a feedback loop and a resistance R32 is provided at the positive input in+. A resistance R1 is provided at the output of the amplifier U9. The resistance R4 is coupled to a capacitor C4 which in turn is coupled to a negative input connection IN− of a digital power amplifier U14. The resistance R1 is coupled via a capacitor C13 to the positive input IN+ of the digital power amplifier U14. The digital power amplifier U14 is therefore coupled both to earth and to the operating voltage V_{cc}. The amplifier U14 is a digital power amplifier and has two outputs, namely a positive output Out+ and a negative output Out−. A first smoothing circuit (110) consisting of the coil L2, the capacitor C6 and the series circuit comprising the capacitor C11 and the resistance R9 is provided at the positive output Out+. A second smoothing circuit 120 consisting of the coil L1, the capacitor C1 and the series circuit comprising a capacitor C8 and the resistance R10 is provided at the negative output Out−.

Thus, the first and second smoothing circuits 110, 120 are provided at the output of the power amplifier U14. Furthermore, a first and second feedback unit 130, 140 is provided in each case from the output of the smoothing unit at an input of the amplifier U14. The first and second feedback circuit 130, 140 each have a parallel circuit comprising a capacitor and a resistance (C7, R3 and C2, R2). The first feedback unit 130 returns the output of the first smoothing circuit 110 to the output of the resistance R4 and is thus coupled via the capacitor C4 to the input connection IN− of the amplifier U14. The second feedback 140 extends between the output of the second smoothing circuit 120 and the resistance R1 Thus, the second feedback loop 140 is coupled via the capacitor C13 to the positive input IN+ of the amplifier U14.

The digital power amplifier U14 (Class D amplifier) is characterized in that it converts an analog electric input signal at the input (in+, in−) into a pulse-width-modulated power-amplified output signal (at the output (Out+, Out−). The output signal has a constant amplitude and frequency and a variable pulse width corresponding to the amplitude of the input signal. The frequency lies significantly above the relevant signal frequencies for the audio range. As a result, the electrical losses in the power amplifier can be reduced considerably and a high efficiency can be achieved. The power-amplified input signal can be reconstructed at the output by a low-pass filter (i.e. by the smoothing circuit 110, 120) whereby the signal components having frequencies above the audio frequency range are damped by a low-pass filter. The passive low-pass filter can be a source of nonlinearities which result in perturbing distortions in the audio range. These nonlinearities can then be reduced by the feedback loops.

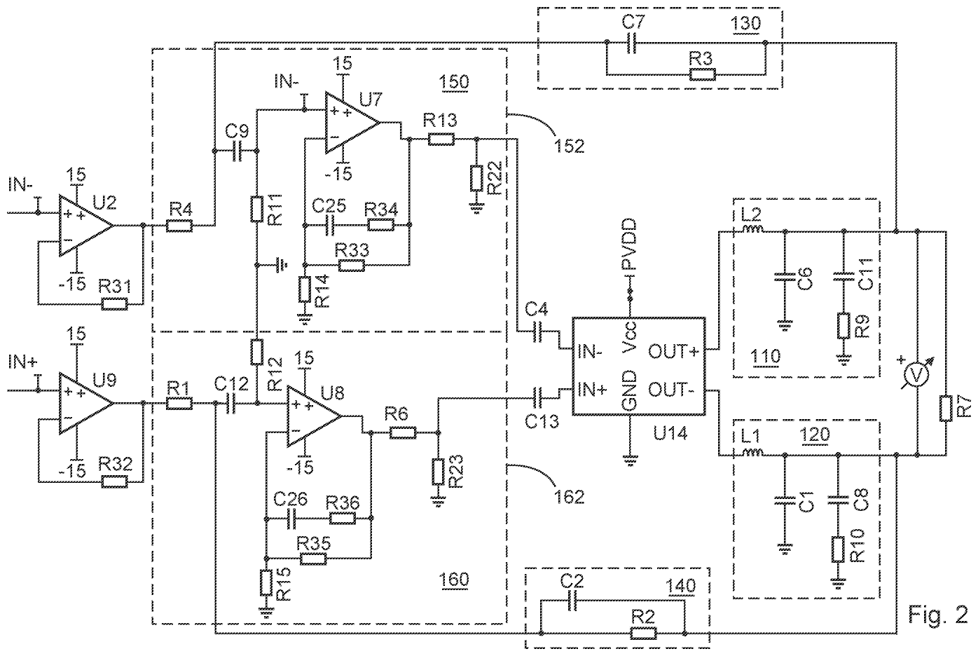

FIG. 2 shows a circuit diagram of an alternative loudspeaker amplifier. The circuit of FIG. 2 is based on the circuit of FIG. 1 and has a positive and negative input connection in−, in+, two pre-amplifiers U2, U9, a digital power amplifier U14, a first and second smoothing circuit 110, 120 at the output of the power amplifier U14 and a first and second feedback unit 130, 140. In addition to the circuit of FIG. 1, the circuit according to FIG. 2 has a first and a second active amplification circuit 150, 160 as part of the feedback of the power amplifier, i.e. a first and second feedback circuit. The first active amplification circuit 150 is coupled to the negative input in− whilst the second active amplification circuit 160 is coupled to the positive input in+. The first active amplification circuit 150 is coupled between the output of the amplifier U2 and the capacitor C4. The second active amplification circuit 160 is coupled between the output of the amplifier U8 and the capacitor C13.

The first and second amplifier unit 150, 160 is therefore part of the first and second feed-back circuit. Since active pre-amplifiers U7, U8 are provided, an active amplification in the respective feedback loops is made possible.

The first feedback circuit can therefore comprise the first feedback unit 130 and the first active pre-amplifier circuit 150. The second feedback circuit can comprise the second feed-back unit 140 and the second active amplifier circuit 160.

The first active amplification unit 150 therefore comprises an amplifier U7 with a positive connection and a negative connection and a further circuit (R4, R11, C25, R34, R33, R14, R13, R32, C9). The positive connection is coupled to a capacitor C9 and a resistance R11.

The resistance R11 is coupled to earth. The capacitor C9 is in turn coupled to the resistance R4. The amplifier U7 has a feedback loop which consists of a parallel circuit which comprises a series circuit comprising a capacitor C25 and a resistance R34 as well as a resistance R33. The feedback loop can be coupled to earth via a resistance R14. A voltage divider consisting of a resistance R13 and R22 is provided at the output of the amplifier U7. The first active amplifier unit 150 is coupled to the capacitor C4 at the negative input of the amplifier U14 via the voltage divider. The first active amplification unit 150 has an input 151 at the resistance R4 and an output 152 at the output of the resistance R13.

The second power unit 160 comprises a pre-amplifier U8 and a further circuit (R1, R15, C12, C28, R38, R35, R6, R23). The pre-amplifier U8 is coupled to the resistance R1 via a capacitor C12. Furthermore, a resistance R12 is coupled to the positive input of the amplifier U9. The resistance R12 is further coupled to earth. The pre-amplifier U8 comprises a feedback loop consisting of a parallel circuit, a series circuit of the capacitor C26 and the resistance R36 as well as the resistance R35. The feedback loop is coupled to earth via the resistance R15. A voltage divider comprising a resistance R6 and R23 is coupled at the output of the pre-amplifier. The amplifier U8 is coupled to a positive connection of the amplifier U14 via this voltage divider. The second active amplification unit 160 has an input 161 at the resistance R1 and an output 162 at the output of the resistance R6.

It should be stressed that the feedback circuits are each guided from the negative output to the positive input or from the positive output to the negative input of the power amplifier U14 in order to achieve a negative feedback. The active amplification circuits 150 and 160 are designed as non-inverting amplifier circuits.

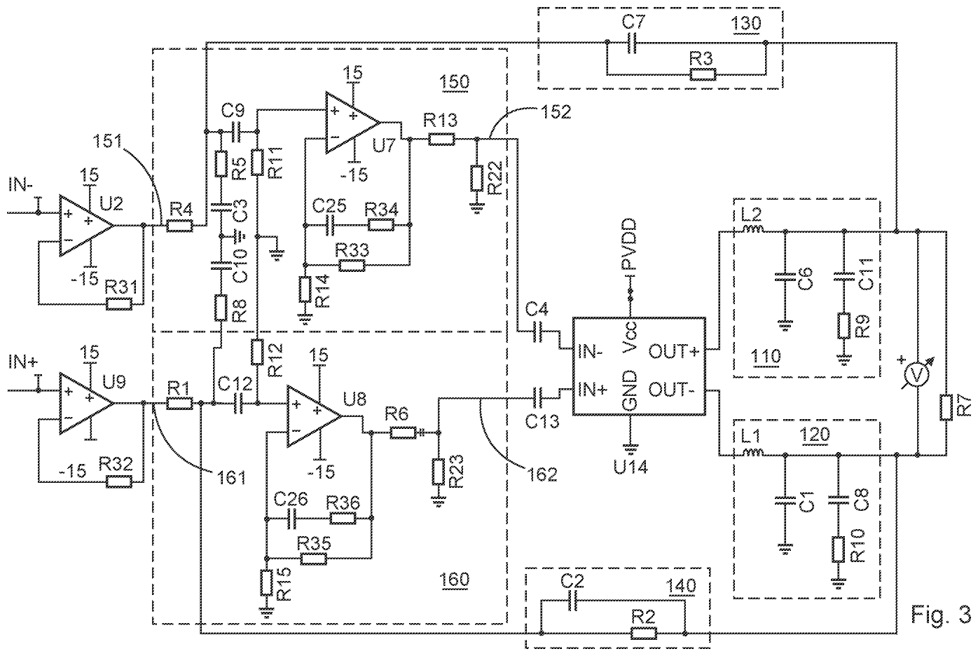

FIG. 3 shows a circuit diagram of another loudspeaker amplifier. The circuit of FIG. 3 is based on the circuit of FIG. 2. Only the first and second active amplifier unit 150, 160 is configured differently. In this case, in addition the resistance R5 is provided in series with a capacitor C3 in the first active amplifier unit 150 and the resistance R8 is provided in series with a capacitor C10 in the second active amplifier unit 160. The remaining circuit corresponds to the circuit of FIG. 2. Thus, a series circuit comprising the resistance R5, the two capacitors C3, C10 and the resistance R8 is provided.

The feedback circuits are each guided from the negative output to the positive input or from the positive output to the negative input of the power amplifier U14 in order to achieve a negative feedback.

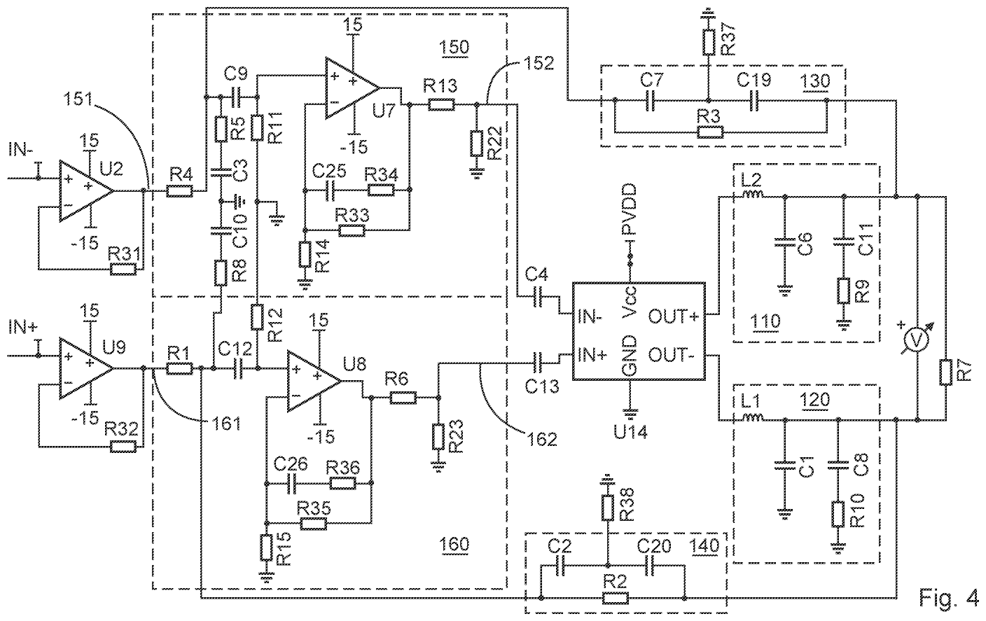

FIG. 4 shows a circuit diagram of another loudspeaker amplifier. The circuit of FIG. 4 is based on the circuit of FIG. 3, wherein the first and second feedback unit 130, 140 is modified. In the first feedback unit 130, in addition to the capacitor C7 and the resistance R3 a further capacitor 019 and a resistance R37 are provided, which is coupled between the capacitor C7 and the capacitor C9 on the one hand and to earth on the other hand.

Accordingly, in addition to the resistance R2 and the capacitor C2, a capacitor C20 and a resistance R38 is provided in the second feedback unit 140. The resistance R38 is coupled to earth on the one hand and on the other hand between the two capacitors C2, C20.

As a result of the combination of the first and second feedback unit 130, 140 and of the first and second active amplifier unit 150, 160, the feedback for the power amplifier U14 can be improved appreciably. In particular, the output signal of the power amplifier U14 can be smoothed (by means of the first and second smoothing unit 110, 120) without resulting in increased distortion here. This is achieved by the first feedback unit 130 and the first active amplifier unit 150 as well as by the second feedback unit 140 and the second active amplifier unit 160. A feedback amplification in particular in the audio frequency range can be enhanced by this special arrangement.

Optionally the first and second active amplifier unit 150, 160 can return their respective amplification to 1 at higher frequencies, for example, >20 kHz.

Optionally the amplifier U14 can operate as a 0 dB amplifier from a frequency of >20 kHz.

According to one aspect of the present invention, a power amplifier is provided for a loudspeaker which has a feedback at the output of the power amplifier which is returned to an analog pre-amplifier.

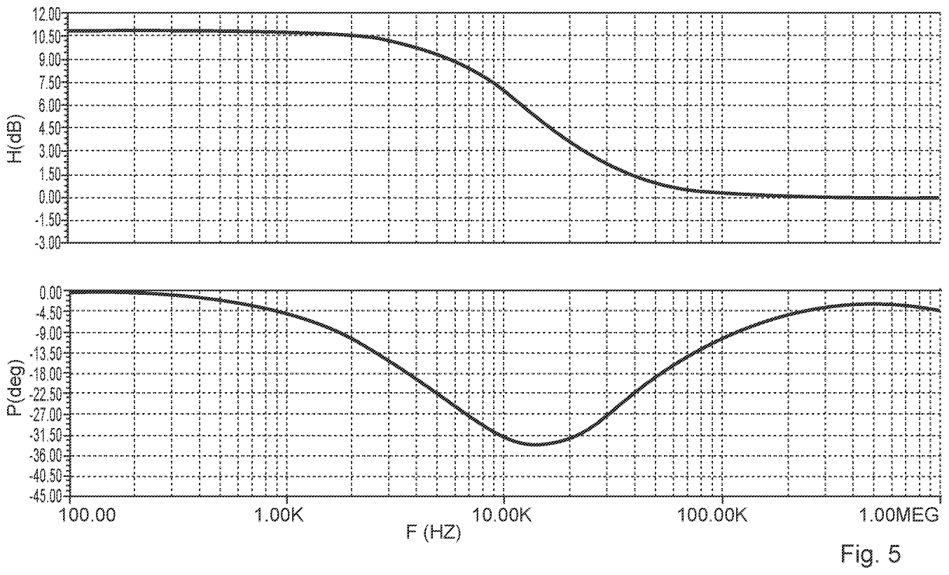

By providing the amplifiers U7, U8, an intrinsic noise of the power amplifier U14 can be reduced by about 10 dB for the conditions shown in FIG. 5 and amplification G not further quantified and network 130, 140 from FIG. 4. This is also the case if an integrated power io amplifier is involved. The reduction in noise and nonlinearity can also have higher values than 10 dB depending on the circuit design.

The feedback circuits are each guided from the negative output to the positive input or from the positive output to the negative input of the power amplifier U14 to achieve a negative feedback.

FIG. 5 shows a diagram of the phase and the magnitude of the signals of an active feed-back circuit 150, 160. FIG. 5 shows the amplification H and the phase P of the power amplifier as a function of the frequency F. In particular, the frequency response from the input 151, 161 to the output 152, 162 of the active amplifier circuit 150, 160 is shown.

The amplification H can be high, for example, up to 1 kHz, e.g. greater than 6 dB and can then decrease until it is lower than 1 dB from 70 kHz. The phase P decreases slowly between 100 Hz and 1 kHz. A continuous decrease takes place between 1 kHz and about 10 kHz. The phase then increases again at higher frequencies and approaches 0°. In a range from 70 kHz to at least 500 kHz the phase remains above −15°.

According to one aspect of the present invention, a power amplifier is provided for a loudspeaker which has a feedback with a frequency-dependent amplification. The amplifiers U7, U8 are used for pre-amplification and are located within one of the feedbacks for the power amplifier U14. As a result, the intrinsic noise of the power amplifier U14 and the nonlinear distortions of an output low-pass filter 110, 120 can be reduced by 10 dB for example.

According to one aspect of the present invention, the power amplifier U14 is configured as a CLASS D end stage and for example, has a 0 dB gain crossover frequency at about 100 kHz.

According to one aspect of the present invention, the first and second active amplifier circuit 150, 160 is not effective at a frequency of 100 kHz. On the other hand, the first and second active amplifier circuit 150, 160 operate with an amplification of 1. This is advantageous in order not to cause any significant phase shift at the gain crossover frequency of the power amplifier U14.

The invention relates to an external circuit of an integrated power amplifier to improve and adapt the non-accessible properties of the amplifier. The amplification which frequently has a non-variable value in integrated power amplifiers can thus be adapted. Without the present invention this results in disadvantages since the overall transmission sensitivity as a combination of loudspeaker and amplifier only takes place with a deterioration of the signal-noise ratio if signal damping is necessary before the power amplifier.

1. A loudspeaker power amplifier, comprising:
a digital amplifier, having a negative input and a positive input and a negative output and a positive output and
a first feedback circuit from the positive output to the negative input
a second feedback circuit from the negative output to the positive input
wherein the first and the second feedback circuit each have a first and second active amplification circuit.

2. A loudspeaker power amplifier according to claim 1, further comprising:
a first smoothing circuit at the positive output of the digital amplifier for smoothing the output signals of the positive output, and
a second smoothing circuit at the negative output of the digital amplifier for smoothing the output signals of the negative output.

3. A loudspeaker power amplifier according to claim 1, wherein
the first and second active amplifier circuit each have a frequency response with an amplification and a phase,
wherein the amplification at a frequency of 1 kHz is greater than 6 dB and the amplification at frequencies above 70 kHz is less than 1 dB and
wherein the phase in the frequency range of 70 kHz to 500 kHz lies above −15°.

4. A loudspeaker amplifier according to claim 1, wherein
the first and the second feedback circuit each feed back an alternating voltage.

5. A loudspeaker comprising:
a loudspeaker power amplifier according to claim 1.
